(19) United States
(12) Patent Application Publication
(10) Pub. No.: US 2026/0018826 A1
(43) Pub. Date: Jan. 15, 2026

(54) CONNECTOR ASSEMBLY

(71) Applicant: UNIQCONN INC., Seongnam-si (KR)

(72) Inventors: Young Dong KIM, Hwaseong-si (KR); Yong Hun OH, Osan-si (KR); Joung Min PARK, Osan-si (KR); Jong Hyup LIM, Hwaseong-si (KR); Gi Yun UM, Seongnam-si (KR)

(73) Assignee: UNIQCONN INC., Seongnam-si (KR)

(21) Appl. No.: 19/233,697

(22) Filed: Jun. 10, 2025

(30) Foreign Application Priority Data
Jul. 11, 2024 (KR) 10-2024-0091870

(51) Int. Cl. H01R 13/518; G01R 31/28; H01R 13/512

(52) U.S. Cl. CPC H01R 13/518; G01R 31/2884; H01R 13/512

(57) ABSTRACT

The present invention relates to a connector assembly. The connector assembly of the present invention includes a plurality of cables, a plurality of connectors each including a polygonal prism part extending in a longitudinal direction of the plurality of cables and each connected to one side end of one of the plurality of cables, a frame part disposed between the plurality of cables, a first housing including a first through-hole accommodating the plurality of connectors, and a second housing including a first opening accommodating the frame part and at least a portion of the cables and having a stepped portion disposed on an inner peripheral surface, and by the plurality of connectors being inserted into one through-hole disposed in the first housing and the second housing, more connectors can be connected to a limited terminal area.

### CROSS-REFERENCE TO RELATED APPLICATION

This application claims priority to and the benefit of Korean Patent Application No. 2024-0091870, filed on Jul. 11, 2024, the disclosure of which is incorporated herein by reference in its entirety.

### BACKGROUND

### 1. Field of the Invention

The present invention relates to a connector assembly, and more particularly, to a connector assembly including a plurality of connectors.

### 2. Discussion of Related Art

A semiconductor post-process mainly includes wafer testing, packaging, and package testing stages. Here, the package testing stage tests whether a semiconductor device completed through a previous process is good or defective. The package testing stage includes a stage of bringing a test board into contact with the semiconductor device and electrically testing the semiconductor device. A connector and a cable for input/output of a test signal are connected to the test board.

With an increase in the number of functions of a semiconductor integrated circuit, there has been a request for more functions also for a test board. Accordingly, providing more circuits in a test board and connecting more cables to the test board have become well-known tasks of post-process companies. However, the time and cost for testing each semiconductor integrated circuit increase with an increase in the number of types of tests performed for each semiconductor integrated circuit and an increase in the number of cables connected to the test board. Thus, the proportion of the testing cost relative to the total device cost is increasing.

A connector assembly that allows a plurality of cables to be simultaneously connected and separated is being developed to shorten the time for connecting and separating a plurality of cables to and from a test board. A task using a connector assembly including a plurality of cables can shorten the task time compared to a task of connecting and separating individual cable assemblies one by one. However, since more circuits are provided in a test board, it is becoming more and more difficult to connect more cables to a limited terminal area. Accordingly, the conventional connector assembly device has limitations in allowing more connectors to be included and increasing the connection efficiency.

Therefore, there is a need for technology that can address the above problems.

Meanwhile, the above-described background art is technical information that the inventor possessed for derivation of the disclosure or acquired during the derivation process of the disclosure, and cannot necessarily be said to be known art disclosed to the general public prior to filing the present invention.

### RELATED ART DOCUMENT

### Patent Document

(Patent Document 1)
Related Art Document 1: Korean Patent Publication No. 10-2008-0103337 (Date of Publication: Nov. 27, 2008)

### SUMMARY OF THE INVENTION

The present invention is directed to providing a connector assembly addressing a problem in which the task time and cost increase in a task of connecting and separating a plurality of individual cables.

The present invention is also directed to providing a connector assembly capable of connecting more connectors to a limited terminal area by reducing the size of the connector assembly and increasing the number of connector channels.

Objectives of the present invention are not limited to those mentioned above, and other unmentioned objectives should be clearly understood by those of ordinary skill in the art based on the description below.

A connector assembly according to one embodiment of the present invention for achieving the above objectives includes a plurality of cables, a plurality of connectors each including a polygonal prism part extending in a longitudinal direction of the plurality of cables and each connected to one side end of one of the plurality of cables, a frame part disposed between the plurality of cables, a first housing including a first through-hole accommodating the plurality of connectors, and a second housing including a first opening accommodating the frame part and at least a portion of the cables and having a stepped portion disposed on an inner peripheral surface.

According to another feature of the present invention, the polygonal prism parts may constitute one connector block by being arranged in close contact with other polygonal prism parts, and the connector block may be accommodated in the first through-hole of the first housing and the first opening of the second housing.

According to still another feature of the present invention, the polygonal prism parts may constitute the one connector block by each including a hexagonal prism and at least three hexagonal prisms being arranged in close contact, and the one connector block may include an arrangement structure in which corners of the hexagonal prisms come into contact at one point.

According to yet another feature of the present invention, the plurality of connectors may each further include a cylindrical part extending in the longitudinal direction, the cylindrical part may be disposed at one side end of the polygonal prism part in the longitudinal direction, and a diameter of the cylindrical part on a cross-section perpendicular to the longitudinal direction may be smaller than or equal to a diameter of an inscribed circle of the polygonal prism part on the cross-section perpendicular to the longitudinal direction.

According to yet another feature of the present invention, the first housing may include a circular fixing part accommodating the cylindrical part and a polygonal fixing part accommodating the polygonal prism part.

According to yet another feature of the present invention, the polygonal fixing part may include a corner groove accommodating a corner of the polygonal prism part.

According to yet another feature of the present invention, the frame part may include a plurality of first protruding portions protruding in one direction based on one axis, a plurality of second protruding portions protruding in a direction opposite to the one direction based on the one axis, and third protruding portions protruding in a direction of the one axis, the plurality of first protruding portions and the plurality of second protruding portions may be alternately disposed with each other in both directions, ends of the plurality of first protruding portions and the plurality of second protruding portions may each include a flat surface extending in the longitudinal direction, and the third protruding portions may be coupled in close contact with both side portions of the second housing.

According to yet another feature of the present invention, the frame part and the second housing may surround side portions of the plurality of cables.

According to yet another feature of the present invention, the plurality of cables may be divided into an upper cable block and a lower cable block by a horizontal axis of the frame part, and the second housing may surround an upper portion and a side portion of an outermost cable at one side of the upper cable block and may surround a lower portion and a side portion of an outermost cable at the other side of the lower cable block.

According to yet another feature of the present invention, the frame part and the stepped portion may be disposed to surround the plurality of cables, the stepped portion may press the frame part toward the first housing, and the frame part may press the plurality of connectors toward the first housing.

According to yet another feature of the present invention, the first housing may further include a second through-hole, the second housing may further include a second opening, and the connector assembly may further include additional connectors surrounded by the second through-hole and the second opening and additional cables each connected to one side end of one of the additional connectors.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a perspective view of a connector assembly according to one embodiment of the present disclosure;

FIG. 2 is an exploded perspective view of the connector assembly of FIG. 1;

FIGS. 3A and 3B are front views of one connector and a plurality of connectors according to one embodiment of the present disclosure;

FIG. 4 is a perspective view of a first housing according to one embodiment of the present disclosure;

FIG. 5 is a front view of the first housing accommodating the plurality of connectors according to one embodiment of the present disclosure;

FIG. 6 is a rear view of the first housing accommodating the plurality of connectors according to one embodiment of the present disclosure;

FIG. 7 is a perspective view of a frame part according to one embodiment of the present disclosure;

FIG. 8 is a rear view of the frame part disposed between a plurality of cables according to one embodiment of the present disclosure;

FIG. 9 is a perspective view of a second housing according to one embodiment of the present disclosure;

FIG. 10 is a perspective view of the connector assembly that is taken along line X-X′ of FIG. 1; and

FIG. 11 is an exploded perspective view of a connector assembly according to another embodiment of the present disclosure.

### DETAILED DESCRIPTION OF EXEMPLARY EMBODIMENTS

Advantages and features of the present invention and methods of achieving them will be apparent with reference to the embodiments described below in detail with the accompanying drawings. However, the present invention is not limited to the embodiments disclosed below and can be implemented in various different forms, the present embodiments only make the disclosure of the present invention complete and are provided to fully inform the scope of the invention to those of ordinary skill in the art to which the present invention pertains, and the present invention is only defined by the scope of the claims.

The shapes, sizes, proportions, angles, numbers, and the like disclosed in the drawings for explaining the embodiments of the present invention are illustrative, and the present invention is not limited to the illustrated matters. In addition, in describing the present invention, if it is determined that a detailed description of a related known technology may unnecessarily obscure the gist of the present invention, the detailed description thereof will be omitted. When “including,” “having,” “consisting,” and the like are used in this specification, other parts may be added unless “only” is used. When a component is expressed in a singular form, a plurality of components may be included unless otherwise specified.

In construing a component, the component is construed as including an error or tolerance range even when there is no separate explicit description thereof.

The terms “first,” “second,” and the like may be used herein to describe various components, but the components are not limited by these terms. These terms are only used to distinguish one component from another. Therefore, a first component mentioned below could be termed a second component within the technical spirit of the present invention. Like reference numerals refer to like components throughout unless otherwise specified.

The features of various embodiments of the present invention may be partially or entirely adhered to or combined with each other and may be interlocked and operated in technically various ways as can be readily understood by those of ordinary skill in the art, and the embodiments may be carried out independently of or in association with each other.

The present invention will be described in detail below with reference to the accompanying drawings.

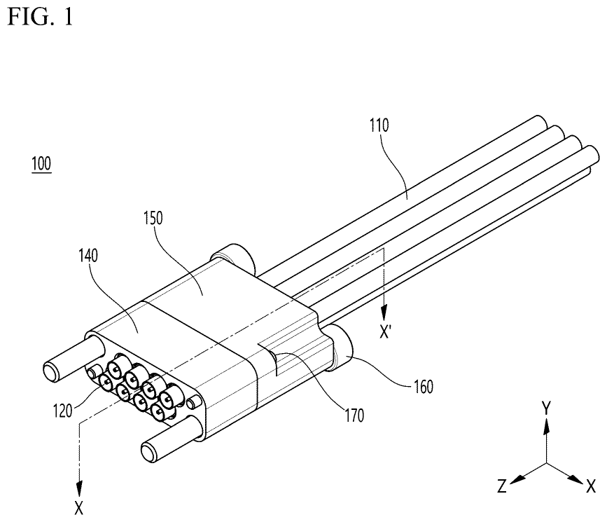

Forward, rearward, upward, downward, leftward, and rightward directions will be referred to in a unified manner throughout based on the directions illustrated in FIG. 1 of the accompanying drawings. The X-axis, Y-axis, and Z-axis directions perpendicular to one another are shown in FIG. 1, and referring to FIG. 1, the X-axis direction indicates a left-right direction, the Y-axis direction indicates an up-down direction, and the Z-axis direction indicates a front-rear direction.

FIG. 1 is a perspective view of a connector assembly according to one embodiment of the present disclosure.

First, referring to FIG. 1, a connector assembly 100 includes a plurality of cables 110, a plurality of connectors 120, a first housing 140, a second housing 150, a bolt 160, and a screw 170. The connector assembly 100 may be connected to a connector jack or a printed circuit board located at a front and may send an electrical signal.

Each of the plurality of cables 110 is a transmission line transmitting an electrical signal. Specifically, the plurality of cables 110 may be coaxial cables. The plurality of cables 110 are connected to a circuit and have a function of transmitting an electrical signal. Specifically, the plurality of cables 110 may be connected to a printed circuit board of a test board through a connector and a connector jack and may transmit various input/output signals. More specifically, the plurality of cables 110 may be connected to a printed circuit board of a test board and may transmit a test driving signal for driving a semiconductor device disposed on the test board or an output signal that allows a state or the like of the semiconductor device to be checked.

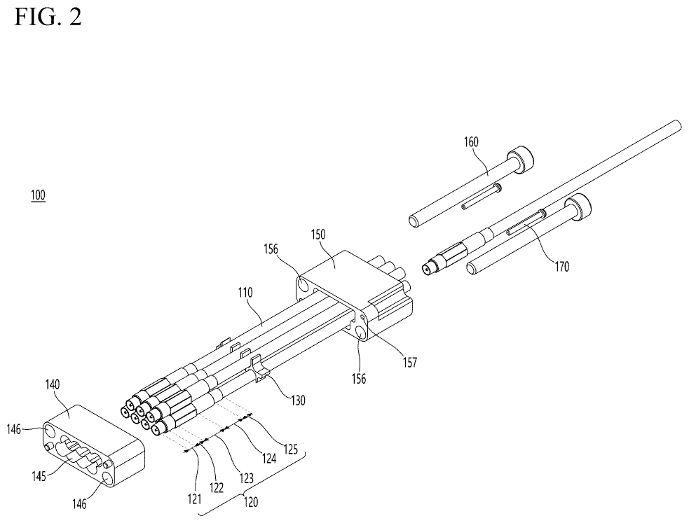

The plurality of connectors 120 each include a terminal contact part, a cylindrical part, a polygonal prism part, a rear prism part, and a cable connecting part. The plurality of connectors 120 may connect the plurality of cables 110 to a printed circuit board. The plurality of connectors 120 are accommodated in the first housing 140 and the second housing 150. A specific form and arrangement relationship of the terminal contact parts or the cable connecting parts of the plurality of connectors 120 will be described below with reference to FIG. 2.

The first housing 140 includes a first through-hole, a bolt fastening hole, and a screw fastening groove. The first housing 140 has a function of accommodating and fixing the plurality of connectors 120. The first housing 140 may limit rotation of the accommodated plurality of connectors 120 about a central axis in the front-rear direction. In addition, the first housing 140 may limit movement of the accommodated plurality of connectors 120 in the forward, upward, downward, leftward, and rightward directions.

The first housing 140 has a rectangular parallelepiped shape in which corners disposed between upper and lower surfaces and left and right surfaces are round. A protruding portion protruding forward may be disposed on a front surface of the first housing 140. Specifically, a protruding portion may be disposed on each diagonal corner on the front surface of the first housing 140. Details of the first through-hole, bolt fastening hole, and screw fastening groove of the first housing 140 will be described below with reference to FIGS. 2 to 6.

The plurality of connectors 120 are arranged in close contact with each other and are accommodated in one through-hole disposed in the first housing 140. Specifically, an empty space may not be present between the plurality of connectors 120, and at least two plurality of connectors 120 may be disposed in close contact with each other in the left-right direction. Thus, more connectors 120 can be accommodated in the first housing 140.

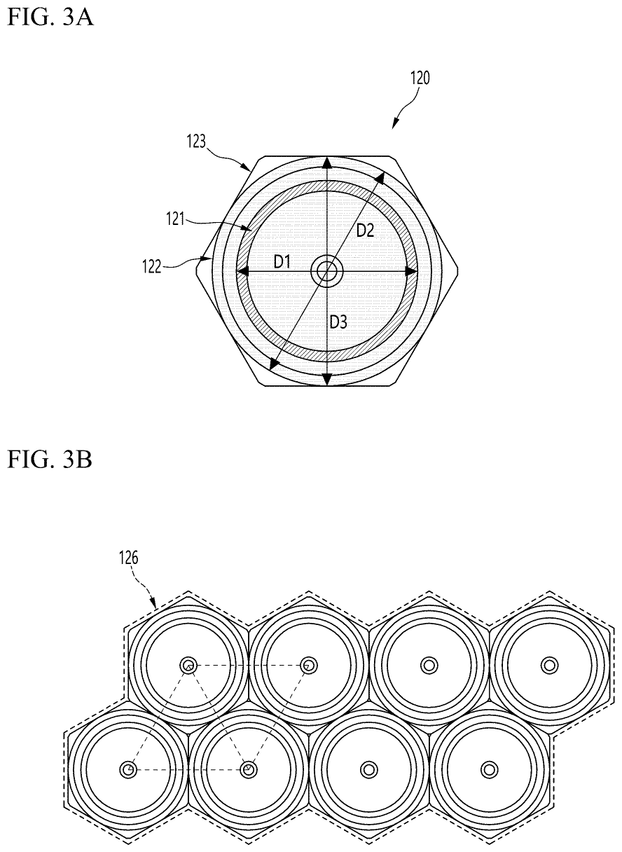

Meanwhile, one side end of each of the plurality of connectors 120 may pass through the first housing 140 and protrude forward. The one side end of each of the plurality of connectors 120 that protrudes to the front of the first housing 140 may be connected to a terminal of a connector jack or a printed circuit board. The close contact arrangement structure of the plurality of connectors 120 will be described below with reference to FIGS. 2 and 3B.

The second housing 150 includes a first opening, a bolt fastening hole, and a screw fastening hole. The second housing 150 has a function of accommodating and fixing at least a portion of each of the plurality of connectors 120 and cables 110. Specifically, the second housing 150 may limit rearward movement of the plurality of connectors 120.

The second housing 150 has a rectangular parallelepiped shape in which corners disposed between upper and lower surfaces and left and right surfaces are round.

Specifically, an outer periphery of a front surface of the second housing 150 may have the same size and shape as an outer periphery of a rear surface of the first housing 140. The front surface of the second housing 150 is disposed to come into contact with the rear surface of the first housing 140.

The second housing 150 may include recessed parts disposed in the corners between the upper and lower surfaces and left and right surfaces. Specifically, the second housing 150 may include recessed parts disposed at corner portions that face each other diagonally. The recessed parts may have a shape that is recessed in a round manner toward the inside of the second housing 150. The recessed parts may continue from one point between the front surface and rear surface of the second housing 150 to the rear surface. A flat surface parallel to the front surface of the second housing 150 and a through-hole vertically passing through the flat surface may be disposed at one point of the recessed parts. A distance from one point of the recessed parts to the front surface of the second housing 150 may be shorter than a length of the screw 170 and longer than or equal to a half of the length of the screw 170. Details of the first opening, the bolt fastening hole, and the screw fastening hole of the second housing 150 will be described below with reference to FIG. 2.

The bolt 160 inserted from the rear surface of the second housing 150 may pass through the second housing 150 and the first housing 140 and may partially protrude toward the front surface of the first housing 140. The protruding portion of the bolt 160 that protrudes toward the front surface of the first housing 140 may be fastened to a connector jack or a printed circuit board that is connected to the connector assembly 100. Accordingly, the bolt 160 may fasten the first housing 140 and the second housing 150 and may additionally fasten the first housing 140 to the connector jack or the printed circuit board. Therefore, the bolt 160 may stably fix connection between the connector assembly 100 and the connector jack or printed circuit board.

The screw 170 inserted from the rear of the second housing 150 passes through the second housing 150 and is inserted into the first housing 140. Accordingly, the screw 170 may fasten the first housing 140 and the second housing 150. The screw 170 may be inserted into a through-hole disposed in a rear surface of the recessed part of the second housing 150. Accordingly, since a thickness of the second housing 150 through which the screw 170 passes becomes thin, the screw 170 having a relatively short length may also fasten the first housing 140 and the second housing 150. Therefore, since the connector assembly 100 of the present embodiment includes the recessed parts of the second housing 150, the types of screws 170 that can be used may be expanded.

Meanwhile, in the connector assembly 100 according to the present embodiment, since the plurality of connectors 120 and cables 110 are accommodated in the first housing 140 and the second housing 150, a worker can simultaneously connect and separate the plurality of connectors 120, and accordingly, the work time can be shortened.

In addition, in the connector assembly 100 according to the present embodiment, since the plurality of connectors 120 are arranged in close contact with each other and accommodated in one through-hole disposed in the first housing 140, more connectors 120 can be accommodated in the first housing 140. Accordingly, in the connector assembly 100, more connectors can be connected to a limited terminal area.

FIG. 2 is an exploded perspective view of the connector assembly of FIG. 1.

Referring to FIG. 2, the plurality of connectors 120 each include a terminal contact part 121, a cylindrical part 122, a polygonal prism part 123, a rear prism part 124, and a cable connecting part 125. The plurality of connectors 120 each include cylindrical and polygonal prismatic shapes that extend in the front-rear direction. The other side end of each of the plurality of connectors 120 is connected to one side end of one of the cables 110. Thus, since the other side end of each of the plurality of connectors 120 is connected to one side end of one of the cables 110, and one side end of each of the plurality of connectors 120 is connected to a connector jack or a printed circuit board, the plurality of connectors 120 can connect the plurality of cables 110 to the connector jack and the printed circuit board. The terminal contact part 121 is disposed at the one side end of each of the plurality of connectors 120 and comes into direct contact with the connector jack or the printed circuit board. The terminal contact part 121 has a hollow cylindrical shape that extends in the front-rear direction, and a connector terminal is disposed in the cylindrical shape. Since the hollow cylinder of the terminal contact part 121 protects the connector terminal therein, and the connector terminal comes into contact with the connector jack or the printed circuit board, the cables 110 and the connectors 120 may be electrically connected to the connector jack or the printed circuit board.

The cylindrical part 122 of each of the plurality of connectors 120 has a cylindrical shape that extends in the front-rear direction. The cylindrical part 122 is disposed behind the terminal contact part 121.

The polygonal prism part 123 of each of the plurality of connectors 120 has a polygonal prismatic shape that extends in the front-rear direction. The polygonal prism part 123 is disposed behind the cylindrical part 122. The polygonal prism parts 123 of the plurality of connectors 120 are arranged in close contact with one another and serve to support one another. Since the polygonal prism parts 123 of the plurality of connectors 120 provide support for one another, the formation of clearances in the close contact arrangement can be prevented. Therefore, through the close contact arrangement of the polygonal prism parts 123, the plurality of connectors 120 can be stably assembled to the first housing 140 without distortion of central axes thereof in the front-rear direction. A specific shape and arrangement relationship of the polygonal prism parts 123 will be described below with reference to FIGS. 3A and 3B.

The rear prism part 124 of each of the plurality of connectors 120 is disposed behind the polygonal prism part 123. The rear prism part 124 may have a cylindrical or polygonal prism shape that extends in the front-rear direction. Specifically, the rear prism part 124 may have a cylindrical shape that extends in the front-rear direction, may have a polygonal prismatic shape that extends in the front-rear direction, or may have a shape in which at least one cylinder extending in the front-rear direction and at least one polygonal prism extending in the front-rear direction are connected in the front-rear direction. In the present embodiment, description will be given based on an example in which the rear prism part 124 has a cylindrical shape that extends in the front-rear direction.

The cable connecting part 125 of each of the plurality of connectors 120 is disposed behind the rear prism part 124. Specifically, the cable connecting part 125 is a portion that is disposed at the other side end of the connector 120 and connected to the one side end of the cable 110.

Referring to FIG. 2, the connector assembly 100 further includes a frame part 130 disposed between the plurality of cables 110. When the first housing 140 and the second housing 150 are fastened, the cylindrical part 122 and the polygonal prism part 123 of each of the plurality of connectors 120 are accommodated in a first through-hole 145 of the first housing 140. In addition, the rear prism part 124 and the cable connecting part 125 of each of the plurality of connectors 120, the frame part 130, and at least a portion of each of the plurality of cables 110 are accommodated in a first opening 155 of the second housing 150.

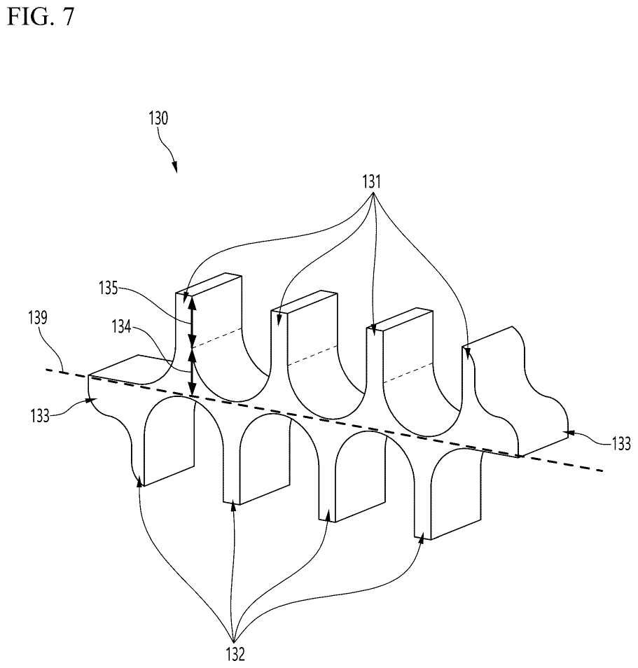

The frame part 130 is disposed between the plurality of cables 110 and fixes each of the plurality of cables 110. The frame part 130 may have a fish bone shape. A specific shape of the frame part 130 will be described below with reference to FIG. 7.

The first housing 140 includes the first through-hole 145 and a bolt fastening hole 146.

The first through-hole 145 is one hole that passes through the front surface and rear surface of the first housing 140. Specifically, the first through-hole 145 may be one through-hole disposed at the center of the front surface and rear surface of the first housing 140. The plurality of connectors 120 may be inserted at one time into the first through-hole 145. The first through-hole 145 may limit rotation of the inserted plurality of connectors 120 about the central axis in the front-rear direction. In addition, the first through-hole 145 may limit movement of the inserted plurality of connectors 120 in the forward, upward, downward, leftward, and rightward directions.

The bolt fastening hole 146 of the first housing 140 is at least one hole that passes through the front surface and rear surface of the first housing 140. Specifically, the bolt fastening hole 146 may be a through-hole disposed in a diagonal corner of each of the front surface and rear surface of the first housing 140. The bolt 160 is inserted into the bolt fastening hole 146. The first housing 140 may be fastened to the second housing 150 by the bolt 160 inserted into the bolt fastening hole 146. In addition, the first housing 140 may be fastened to the connector jack and the printed circuit board by the bolt 160 passing through the bolt fastening hole 146.

The second housing 150 includes the first opening 155, a bolt fastening hole 156, and a screw fastening hole 157.

The first opening 155 is one hole that passes through the front surface and rear surface of the second housing 150. Specifically, the first opening 155 may be one through-hole disposed at the center of the front surface and rear surface of the second housing 150. At least a portion of each of the plurality of connectors 120 and the plurality of cables 110 and the frame part 130 are accommodated in the first opening 155. The first opening 155 may limit rearward movement of the accommodated plurality of connectors 120. In addition, since an inner circumferential surface of the first opening 155 and upper, lower, left, and right surfaces of the frame part 130 are disposed in close contact, the first opening 155 may limit upward, downward, leftward, and rightward movements of the plurality of cables 110 fixed to the frame part 130.

The bolt fastening hole 156 of the second housing 150 is at least one hole that passes through the front surface and rear surface of the second housing 150. Specifically, the bolt fastening hole 156 of the second housing 150 may be a through-hole disposed in a diagonal corner of each of the front surface and rear surface of the second housing 150. More specifically, the bolt fastening hole 156 of the second housing 150 may be disposed at diagonal corners that cross the diagonal corners where the recessed parts of the second housing 150 are disposed. In addition, the bolt fastening hole 156 of the second housing 150 and the bolt fastening hole 146 of the first housing 140 may be disposed at positions overlapping each other in the front-rear direction. The first housing 140 and the second housing 150 may be fastened by the bolt 160 passing through the bolt fastening hole 156 of the second housing 150 and the bolt fastening hole 146 of the first housing 140.

The screw fastening hole 157 of the second housing 150 is at least one hole that passes through the front surface and rear surface of the second housing 150. Specifically, the screw fastening hole 157 of the second housing 150 may be a through-hole disposed in a diagonal corner of each of the front surface and rear surface of the second housing 150. More specifically, the screw fastening hole 157 of the second housing 150 may be disposed at diagonal corners that cross the diagonal corners where the bolt fastening holes 156 of the second housing 150 are disposed. In addition, the screw fastening hole 157 of the second housing 150 may be a throughhole disposed in a rear surface of the recessed part of the second housing 150. The first housing 140 and the second housing 150 may be fastened by the screw 170 passing through the screw fastening hole 157 of the second housing 150 and being inserted into the first housing 140. In addition, by the screw fastening hole 157 of the second housing 150 being disposed at the rear surface of the recessed part of the second housing 150, the length of the screw fastening hole 157 in the front-rear direction may be reduced. Accordingly, even a shorter screw 170 can fasten the first housing 140 and the second housing 150 by passing through the screw fastening hole 157 of the second housing 150.

Meanwhile, the plurality of connectors 120 pass through the first opening 155 from the rear surface of the second housing 150 and are inserted into the first through-hole 145 from the rear surface of the first housing 140. Specifically, the terminal contact part 121 of each of the plurality of connectors 120 passes through the first housing 140 and protrudes to the front of the first housing 140, and the cylindrical part 122 and the polygonal prism part 123 of each of the plurality of connectors 120 are accommodated in the first through-hole 145 of the first housing 140. In addition, the rear prism part 124 and the cable connecting part 125 of each of the plurality of connectors 120 are accommodated in the first opening 155 of the second housing 150.

According to various embodiments of the present invention, the plurality of connectors 120 may each include a pogo pin therein. Specifically, a connector terminal of the terminal contact part 121 of the connector 120 may be a pogo pin. More specifically, one side end of the pogo pin may be disposed at the terminal contact part 121 and may come into contact with the connector jack or the printed circuit board, and the other side end of the pogo pin may be disposed at the cable connecting part 125 of the connector 120 and may be connected to the one side end of the cable 110. Thus, by the plurality of connectors 120 each including a pogo pin, the strength of contact with the connector jack or the printed circuit board can be increased.

Referring to FIG. 2, a method of assemblying the connector assembly 100 may be as follows. The plurality of connectors 120 each connected to one of the plurality of cables 110 pass through the first opening 155 from the rear surface of the second housing 150. The plurality of cables 110 passing through the first opening 155 are fixed to the frame part 130. The polygonal prism parts 123 of the plurality of connectors 120 are arranged in close contact with one another and form a connector block. The connector block is inserted into the first through-hole 145 from the rear surface of the first housing 140. The second housing 150 moves toward the first housing 140 so that the front surface of the second housing 150 and the rear surface of the first housing 140 come into contact. The screw 170 is fastened to the screw fastening hole 157 of the second housing 150 and a screw fastening groove 147 of the first housing 140. The bolt 160 is fastened to the bolt fastening hole 156 of the second housing 150 and the bolt fastening hole 146 of the first housing 140. A specific shape of the connector block will be described below with reference to FIG. 3B.

FIGS. 3A and 3B are front views of one connector and a plurality of connectors according to one embodiment of the present disclosure.

Referring to FIG. 3A, when the connector 120 is viewed from the front, a diameter D10 of the hollow cylinder of the terminal contact part 121 is smaller than or equal to a diameter D2 of the cylindrical part 122. In addition, from the front of the connector 120, the diameter D2 of the cylindrical part 122 of each of the plurality of connectors 120 is smaller than or equal to a diameter D3 of an inscribed circle of the polygonal prism part 123. Thus, from the front of the connector 120, an outer periphery of the polygonal prism part 123 may have a corner that protrudes more than an outer periphery of the cylindrical part 122.

Referring to FIG. 3B, the polygonal prism parts 123 of the plurality of connectors 120 may be arranged in close contact with one another to constitute a connector block 126. The polygonal prism part 123 may have the shape of a triangular prism or a prism with 2n sides. For example, the polygonal prism part 123 may have the shape of a triangular prism, a quadrangular prism, a hexagonal prism, an octagonal prism, or the like. In the present embodiment, description will be given based on an example in which the polygonal prism part 123 has the shape of a hexagonal prism.

The connector block 126 may include an arrangement structure in which one polygonal prism part 123 comes into contact with at least two polygonal prism parts 123. Specifically, when centers of the polygonal prism parts 123 adjacent to each other on a front surface of the connector block 126 are connected to each other, the connector block 126 may include an arrangement structure in which lines connecting the centers of the polygonal prism parts 123 adjacent to each other constitute the shape of an equilateral triangle, a square, a rhombus, or a regular hexagon. For example, as illustrated in FIG. 3B, when the polygonal prism part 123 of each of the plurality of connectors 120 has the shape of a hexagonal prism, one polygonal prism part 123 come into contact with at least two polygonal prism parts 123, and lines connecting the centers of the polygonal prism parts 123 adjacent to each other constitute the shape of an equilateral triangle. Thus, since the connector block 126 includes an arrangement structure in which corners of three different hexagonal prisms come into contact at one point, the close contact arrangement of the plurality of connectors 120 can be stably maintained.

Since the connector assembly 100 according to the present embodiment includes the connector block 126 in which the polygonal prism parts 123 of the plurality of connectors 120 are arranged in close contact, the plurality of connectors 120 of the connector block 126 can be simultaneously inserted into the first housing 140 while the central axis of each of the plurality of connectors 120 is not distorted. In addition, since the plurality of connectors 120 inserted into the first housing 140 support one another, the formation of clearances in the close contact arrangement can be prevented.

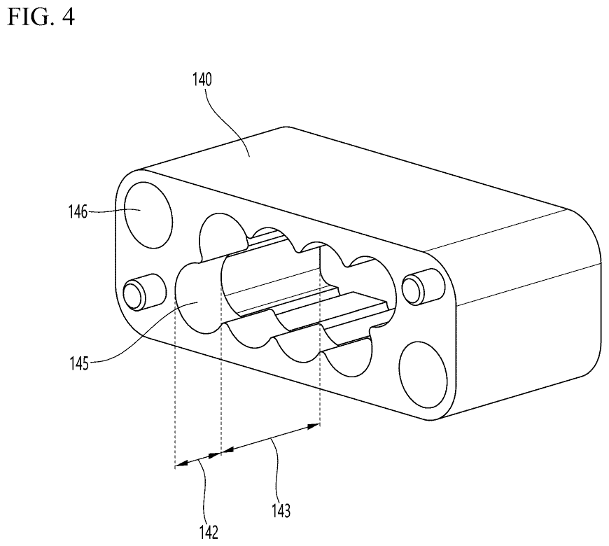

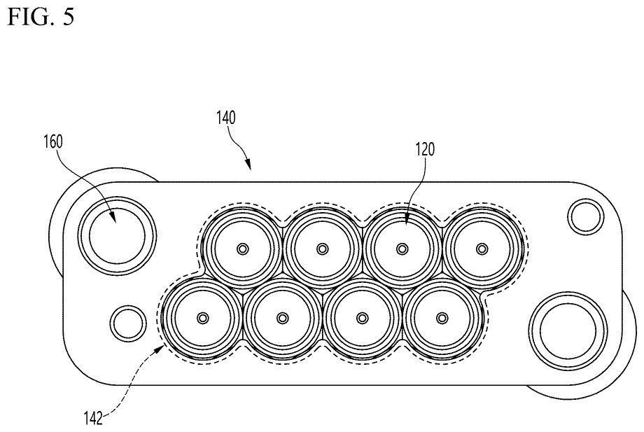

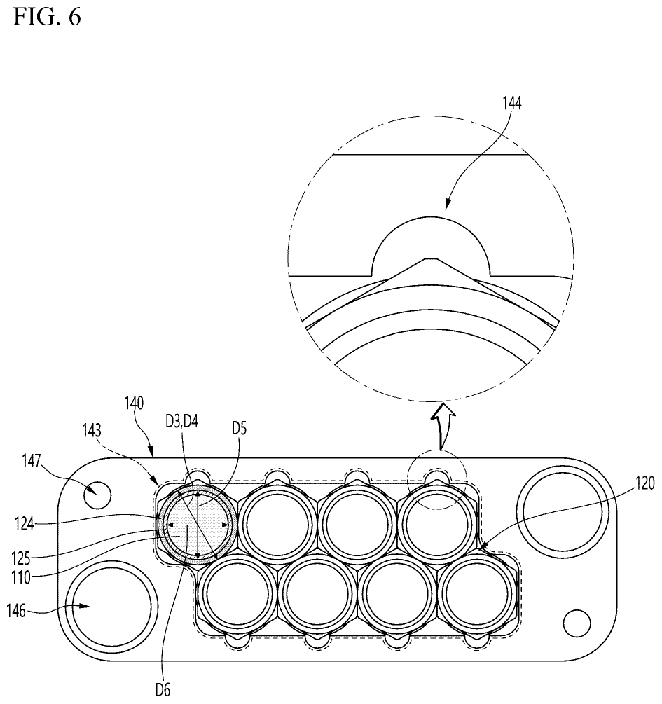

FIG. 4 is a perspective view of a first housing according to one embodiment of the present disclosure. FIG. 5 is a front view of the first housing accommodating the plurality of connectors according to one embodiment of the present disclosure. FIG. 6 is a rear view of the first housing accommodating the plurality of connectors according to one embodiment of the present disclosure.

Referring to FIGS. 4, 5, and 6, the first through-hole 145 of the first housing 140 includes a circular fixing part 142, a polygonal fixing part 143, and a corner groove 144.

The circular fixing part 142 is an area in which the cylindrical part 122 is accommodated in the first through-hole 145. As illustrated in FIGS. 4 and 5, at the front of the first housing 140, the circular fixing part 142 has a shape that corresponds to outer peripheries of the cylindrical parts 122 of the connector block 126. By surrounding the outer peripheries of the cylindrical parts 122 of the connector block 126, the circular fixing part 142 may limit the movement of the plurality of connectors 120 in the upward, downward, leftward, and rightward directions.

The polygonal fixing part 143 is an area in which the polygonal prism part 123 is accommodated in the first through-hole 145. As illustrated in FIG. 6, a width of the polygonal fixing part 143 in the left-right direction has the same size as a width of the connector block 126 in the left-right direction. Accordingly, since left and right side surfaces of the polygonal fixing part 143 are disposed in close contact with left and right side surfaces of the connector block 126, the polygonal fixing part 143 can fix the close contact arrangement of the connector block 126 to prevent distortion thereof. In addition, the polygonal fixing part 143 may limit the rotation of the plurality of connectors 120 about the central axis in the front-rear direction.

Referring to FIG. 6, the corner groove 144 is a concave portion that is recessed from an inner peripheral surface of the polygonal fixing part 143 toward an outer periphery of the first housing 140. The corner groove 144 may be disposed to correspond to a position of each protruding corner of the connector block 126. Specifically, the corner groove 144 may be disposed to correspond to a position of each corner of the connector block 126 that protrudes toward upper and lower surfaces of the polygonal fixing part 143. The corner grooves 144 may limit the rotation of the plurality of connectors 120 about the central axes thereof in the front-rear direction by accommodating the protruding corners of the connector block 126.

The corner groove 144 may have various shapes. Specifically, the corner groove 144 may have a semicircular shape or a polygonal shape. Specifically, as illustrated in FIG. 6, a corner of the polygonal prism part 123 may be accommodated in the corner groove 144 having a semicircular shape. According to various embodiments of the present invention, the corner groove 144 has the same shape as a corner of the polygonal prism part 123, and the corner groove 144 is disposed in close contact with a protruding corner of the polygonal prism part 123 to surround the same, and in this way, an effect of fixing the connector block 126 by the polygonal fixing part 143 can be enhanced.

Meanwhile, the circular fixing part 142 has a narrower inner circumferential surface than the polygonal fixing part 143. Thus, a step is present between the circular fixing part 142 and the polygonal fixing part 143 inside the first housing 140. A rear surface of the step inside the first housing 140 may be disposed to come into contact with a front surface of a corner of the polygonal prism part 123 that protrudes more than the outer periphery of the cylindrical part 122 at the front surface of the connector block 126. Thus, the step inside the first housing 140 may limit the forward movement of the plurality of connectors 120.

Referring to FIG. 6, the first housing 140 further includes the screw fastening groove 147. The screw fastening groove 147 is a groove that extends from the rear surface of the first housing 140 to the front surface thereof. The screw fastening groove 147 may be disposed in each diagonal corner of the rear surface of the first housing 140. Specifically, the screw fastening groove 147 may be disposed at diagonal corners that cross the diagonal corners where the bolt fastening holes 146 of the first housing 140 are disposed. In addition, the screw fastening groove 147 of the first housing 140 may be disposed at a position that overlaps a position of the screw fastening hole 157 of the second housing 150 in the front-rear direction. The first housing 140 and the second housing 150 may be fastened as the screw 170 passing through the screw fastening hole 157 of the second housing 150 is inserted into the screw fastening groove 147 of the first housing 140.

Meanwhile, referring to FIG. 6, on a cross-section that is perpendicular to the front-rear direction, a diameter D4 of the rear prism part 124 may be smaller than or equal to the diameter D3 of the inscribed circle of the polygonal prism part 123. In addition, a diameter D5 of the cable connecting part 125 may be smaller than the diameter D3 of the inscribed circle of the polygonal prism part 123 and greater than a diameter D6 of the cable 110.

According to one embodiment of the present disclosure, the polygonal prism part 123, the rear prism part 124, and the cable connecting part 125 are separately configured in the connector 120. Thus, the connector 120 may be fixed in close contact in an inner space surrounded by the frame part 130, the first housing 140, and the second housing 150.

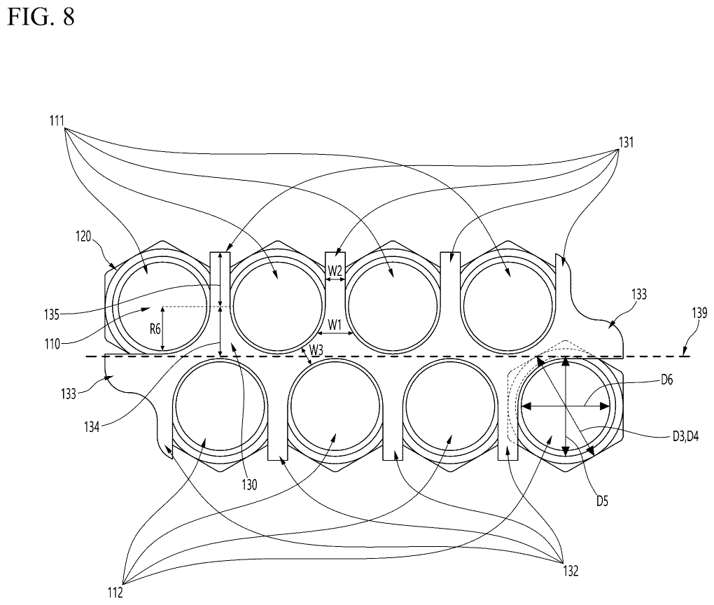

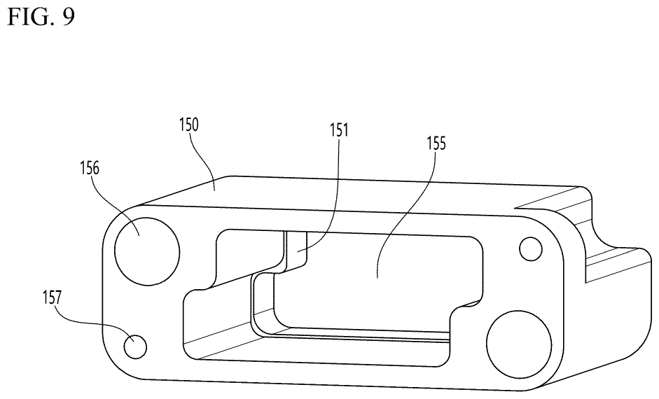

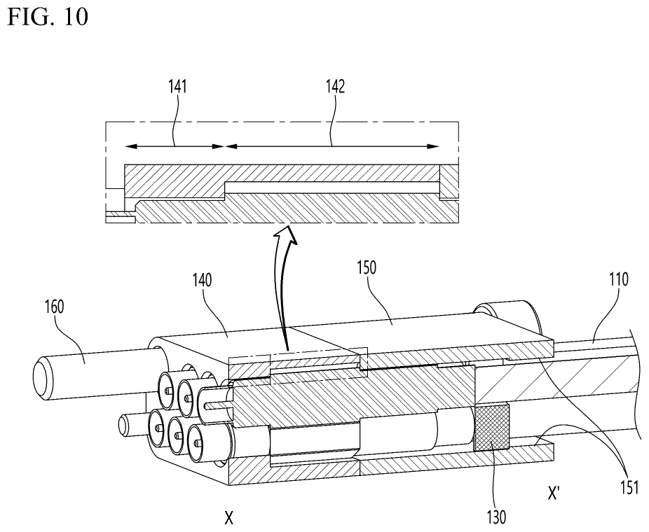

FIG. 7 is a perspective view of a frame part according to one embodiment of the present disclosure. FIG. 8 is a rear view of the frame part disposed between a plurality of cables according to one embodiment of the present disclosure. FIG. 9 is a perspective view of a second housing according to one embodiment of the present disclosure. FIG. 10 is a perspective view of the connector assembly that is taken along line X-X′ of FIG. 1.

Referring to FIGS. 7 and 8, the frame part 130 includes a plurality of first protruding portions 131, a plurality of second protruding portions 132, and third protruding portions 133.

The first protruding portions 131 of the frame part 130 protrude in one direction based on a horizontal axis 139 of the frame part 130. Specifically, the first protruding portions 131 may protrude upward based on the horizontal axis 139 disposed in the left-right direction. In addition, the plurality of second protruding portions 132 protrude in the other direction based on the horizontal axis 139 of the frame part 130. Specifically, the second protruding portions 132 may protrude downward based on the horizontal axis 139 disposed in the left-right direction. The first protruding portions 131 and the second protruding portions 132 may have the same width and height.

The plurality of first protruding portions 131 and the plurality of second protruding portions 132 may be disposed to correspond to the close contact arrangement of the plurality of connectors 120. Specifically, as illustrated in FIG. 8, the first protruding portions 131 protruding upward and the second protruding portions 132 protruding downward may be alternately disposed with each other about the horizontal axis 139. According to various embodiments of the present invention, the first protruding portions 131 protruding upward and the second protruding portions 132 protruding downward may be disposed to overlap each other in the up-down direction.

At a front surface of the frame part 130, the plurality of first protruding portions 131 and the plurality of second protruding portions 132 may each consist of a root portion 134 at one height from the horizontal axis 139 and a pillar portion 135 from a portion past the root portion 134 to an end. Specifically, the one height of the root portion 134 of the protruding portions 131 and 132 from the horizontal axis 139 may be greater than or equal to a radius R6 of the cable 110 on the cross-section that is perpendicular to the front-rear direction.

At the front surface of the frame part 130, a width W1 of the root portion 134 in the direction of the horizontal axis 139 may gradually decrease in a curved shape away from the horizontal axis 139. Specifically, left and right side surfaces of the root portion 134 may have a curved shape whose size and slope are the same as those of a curve of a side portion of the cable 110. Accordingly, as illustrated in FIG. 8, the root portions 134 of two first protruding portions 131 disposed adjacent to each other in the left-right direction may be disposed in close contact with an outer periphery of the cable 110 disposed between the two first protruding portions 131. Meanwhile, when a center of a cable 110 disposed at an upper portion based on the horizontal axis 139 and a center of another cable 110 adjacent thereto and disposed at a lower portion of the horizontal axis 139 are connected with a line, a width W3 of the frame part 130 that overlaps the line is smaller than or equal to a difference between the diameter D3 of the inscribed circle of the polygonal prism part 123 and the diameter D6 of the cable 110 and is greater than a difference between the diameter D3 of the inscribed circle of the polygonal prism part 123 and the diameter D5 of the cable connecting part 125 of the connector 120.

At the front surface of the frame part 130, a width W2 of the pillar portion 135 in the direction of the horizontal axis 139 may have a predetermined width. Specifically, the predetermined width of the pillar portion 135 in the direction of the horizontal axis 139 is smaller than or equal to the difference between the diameter D3 of the inscribed circle of the polygonal prism part 123 and the diameter D6 of the cable 110 and is greater than the difference between the diameter D3 of the inscribed circle of the polygonal prism part 123 and the diameter D5 of the cable connecting part 125 of the connector 120. In addition, a distance between the pillar portions 135 adjacent to each other in the left-right direction is greater than or equal to the diameter D6 of the cable 110 and smaller than the diameter D5 of the cable connecting part 125 of the connector 120. Thus, the front surface of the frame part 130 may be disposed in contact with a rear surface of the cable connecting part 125 of each of the plurality of connectors 120.

Therefore, since the first protruding portions 131 and the second protruding portions 132 of the frame part 130 are disposed in close contact between the plurality of cables 110 while not interfering with the close contact arrangement of the plurality of polygonal prism parts 123, the strength of fixing the plurality of cables 110 can be effectively improved.

Upper surfaces of ends of the first protruding portions 131 and lower surfaces of ends of the second protruding portions 132 may be flat surfaces that extend in the front-rear direction while having a predetermined width in the direction of the horizontal axis 139. The upper surfaces of the ends of the first protruding portions 131 and the lower surfaces of the ends of the second protruding portions 132 may be disposed in contact with inner peripheral surfaces of the second housing 150. Specifically, the upper surfaces of the first protruding portions 131 may come into contact with an upper surface among the inner peripheral surfaces of the second housing 150, and the lower surfaces of the second protruding portions 132 may come into contact with a lower surface among the inner peripheral surfaces of the second housing 150. Accordingly, the frame part 130 may be fixed in the up-down direction in the second housing 150. In addition, since side portions of the plurality of cables 110 disposed between portions of the frame part 130 are surrounded by the frame part 130 and the second housing 150, upward, downward, leftward, and rightward movements of the cables 110 can be limited.

Meanwhile, the first protruding portion 131 and the second protruding portion 132 located at both outermost sides of the frame part 130 in the direction of the horizontal axis 139 may have a shape different from the above-described shathe pe of the first protruding portions 131 and the second protruding portions 132. Specifically, the first protruding portion 131 and the second protruding portion 132 located at the outermost sides may have a shape that corresponds to the shape of a corner of an inner peripheral surface of the first opening 155. More specifically, as illustrated in FIGS. 7 and 8, the first protruding portion 131 at the rightmost side and the second protruding portion 132 at the leftmost side may have a streamlined shape of which a width in the direction of the horizontal axis 139 gradually decreases from the horizontal axis to an end. According to various embodiments of the present invention, the width in the direction of the horizontal axis 139 of the first protruding portion 131 and the second protruding portion 132 located at the outermost sides may linearly decrease to the end and may include a pillar portion having a predetermined width, but the width may be smaller than the width in the direction of the horizontal axis 139 of the first protruding portions 131 at the center. This is due to the shape of the first opening 155 of the second housing 150, and a specific shape of the inner peripheral surface of the first opening 155 of the second housing 150 will be described below with reference to FIG. 9.

Referring to FIGS. 7 and 8, the third protruding portions 133 are portions protruding from both sides in the direction of the horizontal axis 139. Specifically, the third protruding portions 133 may be a portion protruding in one side direction from the root portion 134 of the first protruding portion 131 located at one outermost side in the direction of the horizontal axis 139 and a portion protruding in the other side direction from the root portion 134 of the second protruding portion 132 located at the other outermost side in the direction of the horizontal axis 139. In the present embodiment, description will be given based on an example in which a left-side third protruding portion 133 that protrudes leftward from the root portion 134 of the second protruding portion 132 disposed at the leftmost side and a right-side third protruding portion 133 that protrudes rightward from the root portion 134 of the first protruding portion 131 disposed at the rightmost side are disposed as illustrated in FIG. 8.

Side surfaces of the third protruding portions 133 may be disposed in contact with side surfaces among inner peripheral surfaces of the first opening 155 of the second housing 150. That is, a left side surface of the left-side third protruding portion 133 may come into contact with a left side surface among the inner peripheral surfaces of the first opening 155, and a right side surface of the right-side third protruding portion 133 may come into contact with a right side surface among the inner peripheral surfaces of the first opening 155. Accordingly, the frame part 130 can be fixed in the left-right direction in the second housing 150.

The side surfaces of the third protruding portions 133 are flat surfaces. Specifically, the left side surface of the left-side third protruding portion 133 is a flat surface, and the right side surface of the right-side third protruding portion 133 is a flat surface. Meanwhile, the third protruding portions 133 may include a curved surface. Specifically, as illustrated in FIG. 8, a lower side surface of the left-side third protruding portion 133 and an upper side surface of the right-side third protruding portion 133 may have a curved surface. The curved surfaces of the third protruding portions 133 may correspond to the shapes of the inner peripheral surfaces of the first opening 155 of the second housing 150. Specific shapes of the inner peripheral surfaces of the first opening 155 of the second housing 150 will be described below with reference to FIG. 9.

Referring to FIG. 8, the plurality of cables 110 may be divided into an upper cable block 111 and a lower cable block 112. Specifically, the plurality of cables 110 disposed at an upper portion based on the horizontal axis 139 constitute the upper cable block 111, and the plurality of cables 110 disposed at a lower portion based on the horizontal axis 139 constitute the lower cable block 112.

The frame part 130 is disposed between the plurality of cables 110. As illustrated in FIG. 8, since a diameter of the cable 110 at the cross-section that is perpendicular to the front-rear direction may be smaller than a diameter of the connector 120, separation spaces may be present between the cables 110 unlike between the connectors 120 arranged in close contact with one another. By being disposed in the separation spaces between the plurality of cables 110, the frame part 130 may prevent the plurality of cables 110 from being entangled and may limit the movement of the plurality of cables 110 in the upward, downward, leftward, and rightward directions.

The frame part 130 and the second housing 150 may surround side portions of each of the plurality of cables 110. Since the root portions 134 of the first protruding portions 131 and the second protruding portions 132 of the frame part 130 have the curved shape whose size and slope are the same as those of the outer peripheries of the cables 110, the frame part 130 can come into close contact with the side surfaces of the cables 110. The frame part 130 and the plurality of cables 110 accommodated in the second housing 150 may be covered by the inner peripheral surfaces of the first opening 155 of the second housing 150. Specifically, an upper side portion of the upper cable block 111 and a lower side portion of the lower cable block 112 may be covered by an upper surface and a lower surface of the first opening 155, respectively, and the cables 110 disposed at the outermost peripheries in the left-right direction may be covered by the left and right surfaces of the first opening 155. Accordingly, upward, downward, leftward, and rightward movements of each of the plurality of cables 110 accommodated in the second housing 150 can be limited by the frame part 130 and the inner peripheral surfaces of the second housing 150.

Referring to FIG. 9, at the front surface of the second housing 150, the bolt fastening hole 156 may have a diameter that is greater than a diameter of the screw fastening hole 157. Thus, the inner peripheral surface of the first opening 155 that is adjacent to the bolt fastening hole 156 may have a convex shape that is inserted inward. Accordingly, referring to FIGS. 8 and 9, the first protruding portion 131 at the rightmost side, the second protruding portion 132 at the leftmost side, and the third protruding portions 133 of the frame part 130 that come into contact with areas of the inner peripheral surfaces of the first opening 155 that are adjacent to the bolt fastening hole 156 may have outer peripheral surfaces that correspond to the convex shape of the inner peripheral surfaces of the first opening 155. Specifically, when the inner peripheral surfaces of the first opening 155 include a curved convex shape, the first protruding portion 131 at the rightmost side, the second protruding portion 132 at the leftmost side, and the third protruding portions 133 may have curved outer peripheral portions. According to various embodiments of the present invention, when the inner peripheral surfaces of the first opening 155 include a right-angled convex shape, the first protruding portion 131 at the rightmost side, the second protruding portion 132 at the leftmost side, and the third protruding portions 133 may also include right-angled outer peripheral surfaces.

Meanwhile, according to various embodiments of the present invention, the bolt fastening hole 156 may have a diameter that is smaller than or equal to a diameter of the screw fastening hole 157. Thus, an inner peripheral surface of the first opening 155 that is adjacent to the screw fastening hole 157 may have a convex shape that is inserted inward. In the connector assembly 100 according to the present embodiment, since the second housing 150 includes the bolt fastening hole 156 disposed adjacent to the first opening 155, areas of the front surfaces of the first housing 140 and the second housing 150 may be reduced. Accordingly, since the areas occupied by the front surfaces of the first housing 140 and the second housing 150 are reduced, more connectors 120 can be connected to a limited terminal area.

In addition, since the inner peripheral surface of the first opening 155 is formed to be convex, a distance between the bolt fastening hole 156 and the first opening 155 of the second housing 150 can be secured. Accordingly, durability for the second housing 150 to withstand stress applied thereto as the bolt 160 is fastened to the bolt fastening hole 156 of the second housing 150 can be secured.

Further, since the first protruding portion 131 at the outermost side, the second protruding portion 132 at the outermost side, and the third protruding portions 133 of the frame part 130 include outer peripheral surfaces that correspond to the convex shape of the inner peripheral surface of the first opening 155, an area of a joining surface between the frame part 130 and the inner peripheral surface of the first opening 155 can be increased. Accordingly, the strength of fixing the frame part 130 accommodated in the second housing 150 can be increased in the up-down direction and the left-right direction.

Referring to FIGS. 9 and 10, the second housing 150 further includes a stepped portion 151. The stepped portion 151 has a shape that is inserted inward from the inner peripheral surface of the first opening 155. A step height of the stepped portion 151 inserted inward from the the inner peripheral surface of the first opening 155 may vary depending on the position. Specifically, the height of the stepped portion 151 disposed at the upper surface and lower surface of the first opening 155 may be smaller than or equal to a value obtained by subtracting the diameter D6 of the cable 110 from a length from the horizontal axis 139 to an end of the first protruding portion 131. In addition, the height of the stepped portion 151 disposed at the left and right side surfaces among the inner peripheral surfaces of the first opening 155 may be smaller than or equal to a value obtained by subtracting the diameter D6 of the cable 110 from the diameter D3 of the inscribed circle of the polygonal prism part 123.

Accordingly, an inward surface of the stepped portion 151 of the second housing 150 may be disposed in contact with the plurality of cables 10 accommodated in the second housing 150. Specifically, as illustrated in FIG. 10, the stepped portions 151 disposed at the upper surface and lower surface of the first opening 155 may come into contact with the upper side portion of the upper cable block 111 and the lower side portion of the lower cable block 112, respectively. Thus, even when disposed between the first protruding portions 131 or the second protruding portions 132 having a height higher than the diameter of the cable 110, each of the plurality of cables 110 may be fixed in the up-down direction by the root portions 134 and the stepped portions 151. In addition, the stepped portion 151 disposed at the left side surface of the first opening 155 may come into contact with the left side portion of the cable 110 disposed at the leftmost side, and the stepped portion 151 disposed at the right side surface of the first opening 155 may come into contact with the right side surface of the cable 110 disposed at the rightmost side. Thus, the cables 110 disposed at the outermost sides can be fixed in the left-right direction by the root portions 134 and the stepped portions 151.

Meanwhile, the stepped portion 151 may be located at an inner peripheral surface adjacent to the rear surface of the second housing 150. A front surface of the stepped portion 151 may be disposed in contact with a rear surface of the frame part 130. Accordingly, the stepped portion 151 may limit the rearward movement of the frame part 130 and the plurality of connectors 120

Referring to FIG. 10, the rear surface of the first housing 140 and the front surface of the second housing 150 are disposed in contact with each other. Since the inner peripheral surface of the first opening 155 at the front surface of the second housing 150 has a size smaller than or equal to a size of the inner peripheral surface of the first through-hole 145 at the rear surface of the first housing 140, a step may be present on an interface between the first housing 140 and the second housing 150. The step may be disposed in contact with a rear surface of the polygonal prism part 123 that protrudes past the outer periphery of the rear prism part 124. Accordingly, the step between the first housing 140 and the second housing 150 may limit the rearward movement of the plurality of connectors 120.

In a process of assembling the connector assembly 100, since the front surface of the second housing 150 moves forward and comes into contact with the rear surface of the first housing 140, the step between the first housing 140 and the second housing 150 may press the rear surface of the polygonal prism part 123 of each of the plurality of connectors 120 forward. Accordingly, since a front surface of the polygonal prism part 123 of each of the plurality of connectors 120 comes into contact with a stepped surface inside the first housing 140, and the rear surface of the polygonal prism part 123 of each of the plurality of connectors 120 comes into contact with the front surface of the second housing 150, the plurality of connectors 120 can be fixed in the front-rear direction.

In addition, in a process in which the second housing 150 moves forward, since the stepped portion 151 of the second housing 150 presses the rear surface of the frame part 130 forward, and the front surface of the frame part 130 presses the rear surface of the cable connecting part 125 of each of the plurality of connectors 120 forward, the plurality of connectors 120 can be fixed in the front-rear direction.

By including the plurality of connectors 120 and the plurality of cables 110, the connector assembly 100 according to the present embodiment can shorten the time taken for the task of connecting and separating cables to and from a printed circuit board.

In addition, since the plurality of connectors 120 are accommodated in one first through-hole 145 and one first opening 155 in the connector assembly 100 according to the present embodiment, more connectors 120 can be connected to a limited terminal area.

Further, since the polygonal prism parts 123 of the plurality of connectors 120 are arranged in close contact with one another in the connector assembly 100 according to the present embodiment, the plurality of connectors 120 can be stably assembled to the first housing 140 without distortion of the axes thereof in the longitudinal direction.

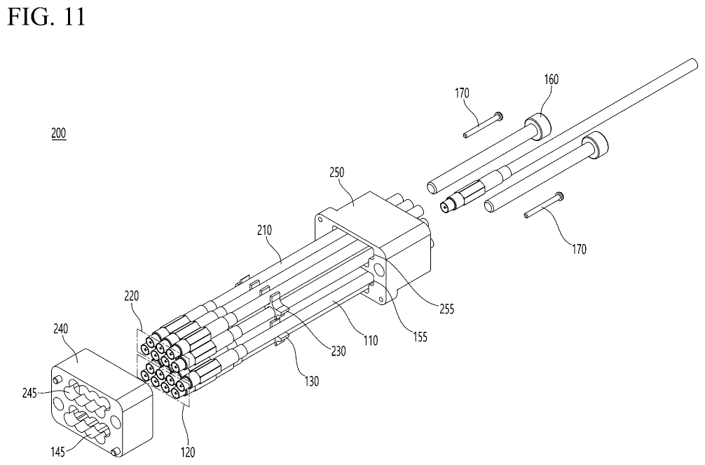

FIG. 11 is an exploded perspective view of a connector assembly according to another embodiment of the present disclosure.

Referring to FIG. 11, a connector assembly 200 according to the present embodiment may further include additional cables 210, additional connectors 220, an additional frame part 230, a second through-hole 245, and a second opening 255 in addition to the components of the connector assembly 100 of FIG. 1. Thus, repeated description of the components substantially the same as those of the connector assembly 100 of FIG. 1 will be omitted.

Each of the additional cables 210 is a transmission line transmitting an electrical signal. Specifically, each of the additional cables 210 may be a transmission line that is substantially the same as the cable 110. That is, each of the additional cables 210 may be configured to have the same form and material as each of the cables 110.

Each of the additional connectors 220 is coupled to one side end of one of the additional cables 210 and connects one of the additional cables 210 to a connector jack or a printed circuit board. As illustrated in FIG. 11, the additional connectors 220 may be configured to have the same form and material as the plurality of connectors 120. According to various embodiments of the present invention, the additional connectors 220 may have a different form from the plurality of connectors 120. Specifically, the polygonal prism part 123 of each of the plurality of connectors 120 may have the shape of a hexagonal prism, and a polygonal prism part of each of the additional connectors 220 may have the shape of a quadrangular prism. The polygonal prism parts of the additional connectors 220 may be arranged in close contact with one another to constitute a connector block.

As illustrated in FIG. 11, the connector block in which the additional connectors 220 are arranged in close contact may have the same shape as the connector block 126 in which the plurality of connectors 120 are arranged in close contact. According to various embodiments of the present invention, the connector block in which the additional connectors 220 are arranged in close contact may have a size and shape different from those of the connector block 126 in which the plurality of connectors 120 are arranged in close contact. Specifically, the connector block in which the additional connectors 220 are arranged in close contact may consist of additional connectors 220 that are smaller in number than the plurality of connectors 120 arranged in close contact in the connector block 126.

The additional frame part 230 includes first protruding portions, second protruding portions, and third protruding portions. Specifically, the additional frame part 230 may be configured to have the same form and material as the frame part 130. By being disposed between the additional cables 210, the additional frame part 230 may sequentially align the additional cables 210. In addition, by being accommodated in the second opening 255 of a second housing 250 and surrounding each of the additional cables 210 together with inner peripheral surfaces of the second opening 255, the additional frame part 230 may limit the movement of the additional cables 210 in the upward, downward, leftward, and rightward directions.

Referring to FIG. 11, a first housing 240 according to the present embodiment further includes at least one second through-hole 245 in addition to the components of the first housing 140 of FIG. 1. Accordingly, the first housing 240 according to the present embodiment may have a wider front surface and rear surface than the first housing 140 of FIG. 1.

The second through-hole 245 is a through-hole that passes through the front surface and rear surface of the first housing 240. One second through-hole 245 accommodates one connector block in which the additional connectors 220 are arranged in close contact. The second through-hole 245 may have the same shape as the first through-hole 145. According to various embodiments of the present invention, the second through-hole 245 may have a different shape from the first through-hole 145. Specifically, since the additional connectors 220 that are smaller in number than the plurality of connectors 120 constitute the connector block, the second through-hole 245 may be formed to be smaller than the first through-hole 145. Meanwhile, the second through-hole 245 may be disposed above the first through-hole 145 as illustrated in FIG. 11. According to various embodiments of the present invention, at least one second through-hole 245 may be disposed below or beside the first through-hole 145.

Referring to FIG. 11, the second housing 250 according to the present embodiment further includes at least one second opening 255 in addition to the components of the second housing 150 of FIG. 1. Accordingly, the second housing 250 according to the present embodiment may have a wider front surface and rear surface than the second housing 150 of FIG. 1.

The second opening 255 is a through-hole that passes through the front surface and rear surface of the second housing 250. The second opening 255 accommodates at least a portion of each of the additional connectors 220 and additional cables 210 and the additional frame part 230.

The second opening 255 may have the same shape as the first opening 155. According to various embodiments of the present invention, the second opening 255 may have a size and shape different from those of the first opening 155. Specifically, since the additional connectors 220 that are smaller in number than the plurality of connectors 120 constitute the connector block, the second opening 255 may be formed to be smaller than the first opening 155. Meanwhile, the second opening 255 may be disposed above the first opening 155 as illustrated in FIG. 11. According to various embodiments of the present invention, at least one second opening 255 may be disposed below or beside the first opening 155.

By including more connectors 120 and 220, the connector assembly 200 according to the present embodiment can shorten the time taken for the task of connecting and separating cables to and from a printed circuit board.

In addition, since the plurality of connectors are accommodated in one through-hole of the first housing 240 in the connector assembly 200 according to the present embodiment, more connectors can be connected to a limited terminal area.

Further, since the first housing 240 includes at least one second through-hole 245 accommodating the plurality of additional connectors 220 in the connector assembly 200 according to the present embodiment, more connectors can be connected to a limited terminal area.

Furthermore, since the connector assembly 200 according to the present embodiment includes the connector block in which the polygonal prism parts of the additional connectors 220 are arranged in close contact, the additional connectors 220 of the connector block can be simultaneously inserted into the first housing 240 while the central axis of each of the plurality of additional connectors 220 is not distorted. In addition, since the plurality of additional connectors 220 inserted into the first housing 240 support one another, the formation of clearances in the close contact arrangement can be prevented.

According to any one of the means for solving the problems by the present invention, since one housing of one embodiment of the present invention accommodates a plurality of connectors at one time, a worker can simultaneously connect and separate the plurality of connectors, and the work time can be shortened.

In addition, according to any one of the means for solving the problems by the present invention, since one hole disposed in a housing of one embodiment of the present invention accommodates a plurality of connectors, more connectors can be connected to a limited terminal area.

In addition, according to any one of the means for solving the problems by the present invention, since polygonal prism parts each disposed on one of a plurality of connectors of one embodiment of the present invention support each other, the plurality of connectors can be stably assembled to a housing.

Effects that can be obtained by the present invention are not limited to those mentioned above, and other unmentioned effects may be clearly understood by those of ordinary skill in the art to which the present invention pertains based on the above description. Embodiments of the present invention have been described in more detail above with reference to the accompanying drawings, but the present invention is not necessarily limited to such embodiments and may be modified in various ways within the scope not departing from the technical spirit of the present invention. Therefore, the embodiments disclosed in the present invention are for describing the technical spirit of the present invention instead of limiting the same, and the scope of the technical spirit of the present invention is not limited by the embodiments. Therefore, the embodiments described above should be understood as illustrative, instead of limiting, in all aspects. The protection scope of the present invention should be construed by the claims below, and all technical ideas within the scope equivalent thereto should be construed as falling within the scope of rights of the present invention.

What is claimed is:

1. A connector assembly comprising:
a plurality of cables;
a plurality of connectors each including a polygonal prism part extending in a longitudinal direction of the plurality of cables and each connected to one side end of one of the plurality of cables;
a frame part disposed between the plurality of cables;
a first housing including a first through-hole accommodating the plurality of connectors; and
a second housing including a first opening accommodating the frame part and at least a portion of the cables and having a stepped portion disposed on an inner peripheral surface.

2. The connector assembly of claim 1, wherein:
the polygonal prism parts constitute one connector block by being arranged in close contact with other polygonal prism parts; and
the connector block is accommodated in the first through-hole of the first housing and the first opening of the second housing.

3. The connector assembly of claim 2, wherein:
the polygonal prism parts constitute the one connector block by each including a hexagonal prism and at least three hexagonal prisms being arranged in close contact; and
the one connector block includes an arrangement structure in which corners of the hexagonal prisms come into contact at one point.

4. The connector assembly of claim 1, wherein:
the plurality of connectors each further include a cylindrical part extending in the longitudinal direction;
the cylindrical part is disposed at one side end of the polygonal prism part in the longitudinal direction; and
a diameter of the cylindrical part on a cross-section perpendicular to the longitudinal direction is smaller than or equal to a diameter of an inscribed circle of the polygonal prism part on the cross-section perpendicular to the longitudinal direction.

5. The connector assembly of claim 4, wherein the first housing includes a circular fixing part accommodating the cylindrical part and a polygonal fixing part accommodating the polygonal prism part.

6. The connector assembly of claim 5, wherein the polygonal fixing part includes a corner groove accommodating a corner of the polygonal prism part.

7. The connector assembly of claim 1, wherein:
the frame part includes a plurality of first protruding portions protruding in one direction based on one axis, a plurality of second protruding portions protruding in a direction opposite to the one direction based on the one axis, and third protruding portions protruding in a direction of the one axis;
the plurality of first protruding portions and the plurality of second protruding portions are alternately disposed with each other in both directions;
ends of the plurality of first protruding portions and the plurality of second protruding portions each include a flat surface extending in the longitudinal direction; and
the third protruding portions are coupled in close contact with both side portions of the second housing.

8. The connector assembly of claim 1, wherein the frame part and the second housing surround side portions of the plurality of cables.

9. The connector assembly of claim 8, wherein:
the plurality of cables are divided into an upper cable block and a lower cable block by a horizontal axis of the frame part; and
the second housing surrounds an upper portion and a side portion of an outermost cable at one side of the upper cable block and surrounds a lower portion and a side portion of an outermost cable at the other side of the lower cable block.

10. The connector assembly of claim 1, wherein:
the frame part and the stepped portion are disposed to surround the plurality of cables;
the stepped portion presses the frame part toward the first housing; and
the frame part presses the plurality of connectors toward the first housing.

11. The connector assembly of claim 1, wherein:
the first housing further includes a second through-hole;
the second housing further includes a second opening; and
the connector assembly further comprises additional connectors surrounded by the second through-hole and the second opening and additional cables each connected to one side end of one of the additional connectors.
